(19) United States
(12) Patent Application Publication
(10) Pub. No.: US 2008/0173349 A1
(43) Pub. Date: Jul. 24, 2008

(54) Solar cells for stratospheric and outer space use

(75) Inventors: Shengzhoug Liu, Rochester Hills, MI (US); Kevin Beernink, (US); Arindam Banerjee, Bloomfield Hills, MI (US); Chi-Chung Yang, Troy, MI (US); Subhendu Guha, Bloomfield Hills, MI (US)

Correspondence Address: ENERGY CONVERSION DEVICES, INC., 2956 WATERVIEW DRIVE, ROCHESTER HILLS, MI, 48309, US

(73) Assignee: United Solar Ovonic LLC

(21) Appl. No.: 11/656,151

(22) Filed: Jan. 22, 2007

(51) Int. Cl. H01L 31/00

(52) U.S. Cl. 136/256

(57) ABSTRACT

A light weight photovoltaic device for use in stratospheric and outer space applications. The device includes a protective surface coating on the light incident side thereof. The protective coating does not deleteriously affect the photovoltaic properties of the solar cell, is formed of a material which protects said solar cell from the harsh conditions in the stratospheric or outer space environment in which the photovoltaic device is adapted to be used; and remains substantially unchanged when exposed to the harsh conditions in the stratosphere or outer space. The protective coating is preferably made of a spray coated silicone based material and is between 0.01 and 2 mil thick.

### GOVERNMENT LICENSE RIGHTS

This invention was made with Government support under U.S. Air Force Contract number F29601-03-C-0122. The Government has certain rights in this invention.

### FIELD OF THE INVENTION

The present invention relates to solar cells for use in the stratosphere on airships and in outer space on spacecrafts. More specifically, the present invention relates to light weight solar cells (specific power: >500 W/kg) and ultralight solar cells (specific power: >1000 W/kg) deposited on polymer or thin metallic films, and including spray coated silicone encapsulants deposited on the top thereof for protection against the atmospheric, stratospheric and outer space environments.

### BACKGROUND OF THE INVENTION

It has become abundantly clear that there is great potential for light weight, flexible solar cells in stratospheric and outer space applications. An example of a stratospheric application is to supply energy to high-altitude platforms. In this regard, the demand for high-capacity wireless services is bringing increasing challenges. Terrestrially, the need for line-of-sight electromagnetic propagation paths represents a constraint unless very large numbers of base-station masts are deployed, and satellite communication systems have capacity limitations. A proffered solution to these problems is the deployment of large quantities of high-altitude platforms (HAPs) operating in the stratosphere at altitudes of about 22 km to provide communication facilities that can exploit the best features of both terrestrial and satellite schemes, but they will need a solar based power structure.

Space based applications include satellites for communication and other uses, as well as space stations, observatories, and other power hungry equipment. There have even been suggestions for high-altitude floating platforms for planetary exploration of, for example, Mars.

In view of these and other potential applications, there has been much work in recent years on making lightweight, flexible solar cells. There has not however been any serious consideration as to the harsh, damaging environments in which these solar cells will be used. In short, there has not been much consideration of how to protect the solar cells from the harmful effects of the stratospheric and outer space environments. There is a need to produce lightweight, flexible solar cells that can withstand the harsh environs of the stratosphere or outer space and still offer strong photovoltaic performance.

The present invention provides for solar cells which are protected from these environments by a thin coating on the light incident surface thereof. The coating is adherent and protects the solar cell from harsh radiant energies, as well as oxidizing elements and temperature extremes/cycling. The coating also protects the solar cell from the ground level terrestrial environment where the solar cells will be stored. Finally the coating itself is not deleteriously effected by the environs which it protects against.

### SUMMARY OF THE INVENTION

The present invention comprises a photovoltaic device adapted for use in a stratospheric or outer space environment. The photovoltaic device includes a substrate and at least one solar cell deposited on the substrate. It further includes a protective coating deposited over and completely encapsulating the one solar cell. The protective coating: a) does not deleteriously affect the photovoltaic- properties of the solar cell; b) is formed of a material which protects said solar cell from the harsh conditions in the atmospheric, stratospheric or outer space environment in which the photovoltaic device is adapted to be used; and c) remains substantially unchanged when exposed to the harsh conditions in the atmospheric, stratospheric or outer space environment in which the photovoltaic device is adapted to be used. Preferably the protective coating is a coating of a silicone based material, such as a spray deposited coating of a silicone based material. The protective coating is between 0.01 and 2 mil thick, more preferably between 0.2 and 2 mil thick, even more preferably between 0.5 and 2 mil thick, and most preferably between 1 and 2 mil thick.

The substrate comprises a thin web, such as a thin web of metal or polymer. The metal may comprise stainless steel and the polymer may comprise polyimide film such as Kapton. The solar cell may comprise at least one solar cell, such as, for example, a triple junction amorphous silicon solar cell. The photovoltaic device may further comprise a back-reflecting structure disposed between the substrate and the solar cell. The device may also include a top conducting layer disposed between the solar cell and said protective coating, which may be made of indium-tin-oxide (ITO). Finally, the device may further include a current collection grid disposed between the top conducting layer and the protective coating.

### BRIEF DESCRIPTION OF THE DRAWINGS

FIG. 1 depicts an example of a solar cell devices onto which the coating of the present invention could be applied;

FIG. 2 plots the quantum efficiency (Q) versus light wavelength curves for six coated solar cells, four of which are encapsulated with the silicone coating of the present invention;

FIG. 3 plots the internal quantum efficiency Qₛ (which is Q/(1−R)) versus light wavelength for the same samples from FIG. 1;

FIG. 4 plots the fill factor (FF) of three sets of solar cell samples (bare/uncoated, silicone coated and acrylic hardcoated) before and after exposure to atomic oxygen;

FIG. 5 plots the fill factor (FF) of coated and uncoated solar cells, before and after specific stages in damp heat testing;

FIG. 6 plots the fill factor (FF) of coated and uncoated solar cells, before and after 1000 thermal cycles from −175° C. to 100° C.;

FIG. 7 plots the total integrated quantum efficiency (Q) values of coated and uncoated solar cells, before and after 500 equivalent-sun-hours (ESH) of UV exposure;

FIG. 8 plots the total integrated quantum efficiency (0) values of solar cells coated with the silicone overcoat of the present invention and uncoated solar cells, before and after either 620 equivalent-sun-hours (ESH) exposure to VUV or 592 equivalent-sun-hours (ESH) exposure to NUV exposure;

FIG. 9(a) plots the fill factor (FF) values of three sets of solar cell samples (bare/uncoated, silicone coated and acrylic hardcoated) before and after about 16 hours of exposure to an atmosphere containing about 1% ozone; and

FIG. 9(b) plots the open-circuit voltage (V_{∝}) values of three sets of solar cell samples (bare/uncoated, silicone coated and acrylic hardcoated) before and after about 16 hours of exposure to an atmosphere containing about 1% ozone.

### DETAILED DESCRIPTION OF THE INVENTION

The present invention comprises encapsulated thin film amorphous silicon alloy solar cells on stainless steel or polymer substrates for satellite and airship applications. The encapsulant layer provides a protective coating on the photovoltaic devices. The encapsulant layer is transparent, flexible, space compatible, and mechanically hard. Also, the coating adheres well to the construction materials of the photovoltaic cells and is a barrier to atmospheric contaminants. Due to the different environments in the stratosphere and space, the encapsulant material must meet many stringent requirements.

The encapsulant coating must accomplish two objectives: 1) protection of the photovoltaic device; and 2) control of the absorptivity and emissivity of the cell. With regard to the first objective, the encapsulant coating will offer protection from: a) terrestrial environmental factors such as humidity and atmospheric contaminants; b) mechanical handling during module/array fabrication and stowing; and c) space and stratospheric environmental factors such as exposure to UV radiation, atomic oxygen, and ozone as well as factors such as electrostatic discharge. With regard to the second factor, the encapsulant coating will tailor the emissive and absorptive properties of the cell such that the cell operates at the desired temperature in the selected environment.

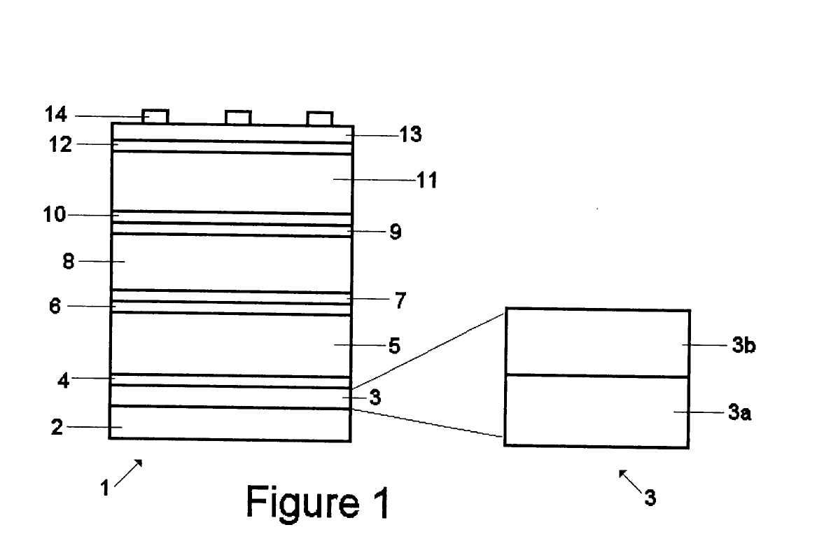

An example of the solar cell devices onto which the coating of the present invention could be applied is shown in FIG. 1. The figure is a schematic depiction of an amorphous silicon photovoltaic device 1 which includes a substrate 2 onto which a back reflector structure 3 is deposited. The structure also includes one or more photovoltaic devices. FIG. 1 depicts a triple junction photovoltaic device including three n-i-p junctions (4-5-6, 7-8-9, and 10-11-12). Although the present drawings depict a triple n-i-p junction solar cell, any type of thin film solar cell would benefit from the protective coating of the present invention. Thus the photovoltaic device of FIG. 1 is depicted to include three n-type semiconductor layers (4, 7 and 10), three intrinsic semiconductor layers (5, 8 and 11) and three p-type semiconductor layers (6, 9 and 12). It should be noted that the thickness of layers of the present figure are not to scale and thus the relative thickness are not indicative of actual relative thicknesses in real devices. Atop the n-i-p junctions is deposited a transparent conductive oxide 13 and grid electrode structure 14. The basic structure of this type of photovoltaic device is well known in the art.

For airship and space applications, the preferred substrate is a thin film of metal or polymer. Preferably the metal substrate may be an ultra thin foil of a non-reactive metal such stainless steel. The preferred polymer substrate is thin film of a stable, non-reactive polymer such as polyimide film like KAPTON™.

The thus the photovoltaic panel of the present invention comprises: 1) a lightweight substrate; 2) at least one thin film amorphous silicon alloy solar cell deposited on the substrate; and 3) an encapsulant layer deposited over the thin film amorphous silicon alloy solar cell. The encapsulant layer is preferably a spray coated thin film of a silicone based material. The coating thickness is preferably between 0.01 and 2 mil thick, more preferably 0.2 mil to 2 mil thick, even more preferably between 0.5 and 2 mil thick, and most preferably 1-2 mil thick. The coating is preferably of uniform thickness and continuous.

As noted above, the encapsulant coating must protect the solar cells in the atmosphere, stratosphere and outer space. The solar cells must be protected from a variety of elements and different types of harmful radiation. The encapsulant must protect the solar cells from all of this while not itself degrading over time and exposure to these conditions and all the while not detracting from the solar cells performance. To determine a suitable coating, the present inventors tested a number of coatings under a variety of conditions to determine the best coating for the solar cells. As noted above a spray coated thin film of a silicone based material performed the best of all the coatings tested.

The coatings that were tested include:

1) a thin SiOₓ film, about 500 Å thick, deposited by a high deposition rate microwave PECVD;

2) a vapor phase polymer (VPP) coat, about 1 micron thick, prepared by high deposition rate microwave PECVD;

3) an acrylic hardcoat less than 0.5 mil thick, prepared by a chemical spray process; and

4) the silicone based overcoat of the present invention, prepared by a chemical spray process.

The thin film SiOₓ coating was applied by a high deposition rate microwave PECVD process using equipment which was used to optimize the deposition process and coating properties of the thin film. The SiOₓ films were on the order of 500 Å thick. The desired encapsulant films were deposited in a thin film batch-type deposition reactor that is equipped with a microwave PECVD excitation source.

The VPP coating is based on a process in which an organometallic Si-containing material is premixed with other gases and fed into a microwave plasma reactor. The gases decompose and react to form a coating. The deposition rate is calibrated by weighing the sample before and after the VPP coating. For tests conducted, the thickness of the VPP coating was controlled at about 1 micron. During initial studies, it was found that the coating delaminates at certain locations/spots. Once the delamination started, it propagated to over the entire surface in two days for a few samples. The delamination process was attributed to cleanliness issues of the substrate surface. An appropriate substrate cleaning process was been developed that led to alleviation of the problem. Although the VPP coating passed many initial screening tests, the thin coating does not seem to protect the wire grids of the solar cells.

The acrylic hardcoat is currently being used in the production line of terrestrial solar panels. It is deposited by a chemical spray process. The standard thickness of the coating in the terrestrial product is over 1 mil. It would be advantageous to reduce this thickness, particularly for airship and space applications given weight considerations. In order to reduce the coating thickness to less than 0.5 mil, an R&D batch spray coating system was designed and constructed. The hardcoat passed several screening tests, but one of the early problems associated with the thin coat is the existence of pinholes in the coating, which allow water vapor and other species easy ingress therethrough. In which case, the encapsulant would not provide adequate protection to the underlying solar cell. Experiments to understand possible causes of pinhole formation as well as the properties of the coating material were undertaken in an attempt to eliminate this problem.

The silicone based overcoat is prepared by a chemical spray process. The samples were spray coated using commercial spray coating equipment. The coating was then cured at elevated temperature. Parameters tested include coating thickness and solvent concentration. Lower dilution leads to textured and thicker coating. Higher dilution results in smooth and thin coating about 0.1 mil. The coating is clear, uniform and passed all screening tests. One example of a suitable silicone based material is DOW CORNING® 1-2620 (Low VOC Conformal Coating or dispersion) which has been diluted with DOW CORNING® OS-30 solvent.

The coating cured using Dow Corning recommended procedure had a few problems. For example, a significant amount of volatile compounds remained in the coating that were released at high temperature. Therefore a process to cure the silicone film at higher temperature of about 125° C. was developed. The high temperature cure allows essentially all volatile compounds to be either transformed into solid coating or evaporated. It has been found that the curing can be done in one of following ways:
1. gradual curing: slowly heat the samples up from low temperature to greater than or equal to 125° C.;
2. multiple-step curing: cure the samples at a low temperature, e.g. 70° C. and then cure them at high temperature to greater than or equal to 125° C.; and
3. one-step curing: set curing oven or system temperature at greater than or equal to 125° C. and cure the solar cells in the oven for a preset amount of time, e.g. 30 minutes. The coatings cured using the above methods haves passed standard outgassing tests as per ASTM-E-595-93 (2003).

As will be further discussed hereinafter, the four coatings were subjected to numerous tests to determine which if any would be a good candidate for coating of solar cells for stratospheric and outer space applications. To that end, the test and results described in the following paragraphs were performed. While all of the potential coatings passed some of the tests, only the silicone-based coating sufficiently passed all of the tests.

### Optical Evaluation

In-house I-V, quantum efficiency (Q), and reflection (R) measurements have been used to evaluate the optical characteristics of the perspective encapsulant coatings, coating processes, and post coating treatments. The encapsulant coating is the first layer that sunlight goes through before it enters the solar cell. The quantum efficiency (Q), and short-circuit current (I_{sc} or J_{sc}) are direct measures of how much light is transmitted into the solar cells by the encapsulant layer. Quantum efficiency (Q) and reflection (R) measurements as a function of wavelength can be correlated to the optical transmission spectrum of the encapsulant coatings. All the encapsulant coatings passed the optical tests. The coatings exhibit Q and J_{sc} losses of only about 1-2% attributable predominantly to reflection losses. An additional antireflection coating will likely restore the initial Q and J_{sc} values.

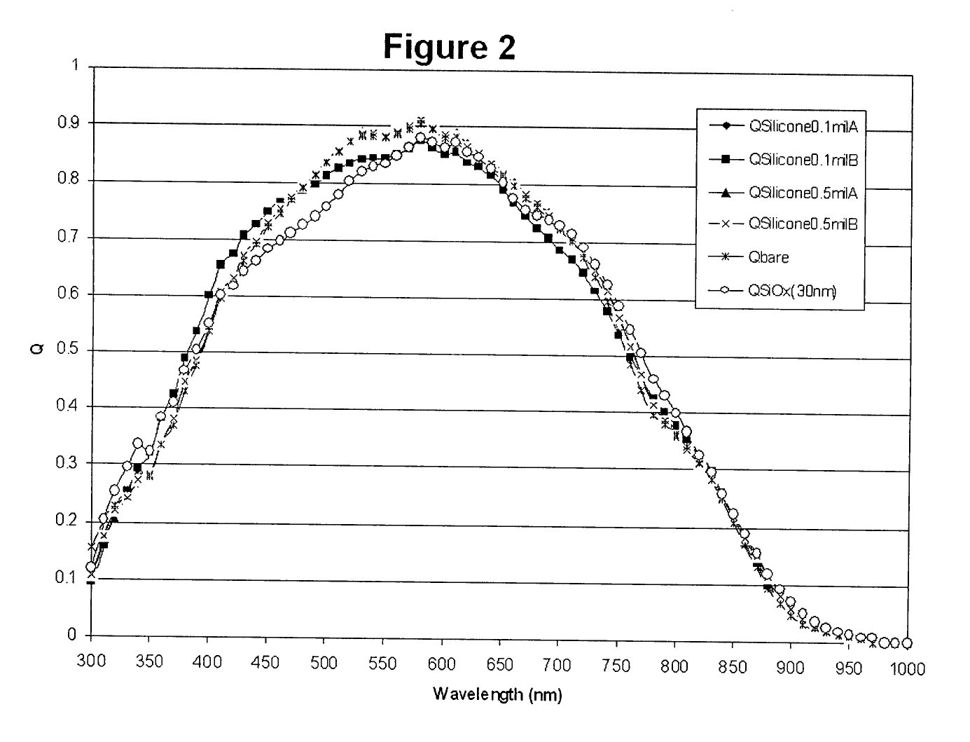

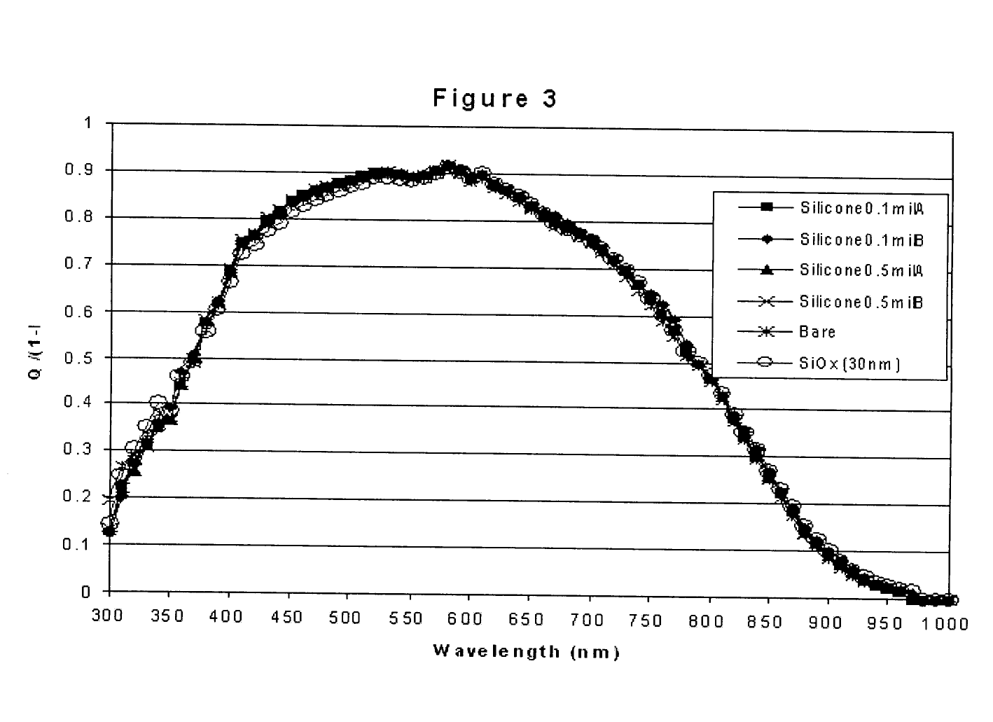

The quantum efficiency (Q) versus light wavelength curves of six samples are plotted in FIG. 2. The sample tests shown in FIG. 2 are: 1) one bare sample with no encapsulant; 2) one sample with a 30 nm SiOₓ coating; 3) two samples with a 0.1 mil silicone coating (A and B), and 4) two samples with a 0.5 mil silicone overcoat (A and B). The coated samples exhibit a reduction in quantum efficiency (Q) after the encapsulant coatings compared to a bare sample without any encapsulant. However, as illustrated in FIG. 3, the internal quantum efficiency Qₛ (which is Q/(1−R)) of all coated samples (including SiOₓ and 0.1 mil and 0.5 mil silicone overcoats) shows no significant change compared to that of the original uncoated bare reference sample. While not shown, the VPP and acrylic hardcoat encapsulants show very similar results. This result shows that the quantum efficiency (Q) loss of the encapsulated samples can be attributed to reflection losses and not optical absorption. As previously stated, an additional antireflection coating should restore the initial Q and J_{sc} values.

### Atomic Oxygen Exposure

It is known that there is atomic oxygen in both space and airship environment. An Ar-O₂ microwave plasma was used as a preliminary screening tool for the atomic oxygen tests. Table 1 lists I-V characteristics of cells before and after the exposure. For this test, all samples are about 2″×2″ in size. During the test, the samples were mounted downstream relative to the plasma to avoid direct interaction with the plasma. As a relative measure, It was found that after two hours of exposure, bare (without encapsulant) and SiOₓ coated samples exhibited extreme degradation in efficiency, losing 54%, 69%, 10%, and 88%, respectively, for the four samples tested. In contrast, samples with VPP and acrylic hardcoat encapsulants incurred only minimum loss in efficiency. In fact, the two VPP samples exhibited less than 1% loss. Note that the plasma exposure is very intense and while it was not calibrated against any standard, it was a preliminary and yet powerful screening tool. Another preliminary test at even further downstream (no direct plasma exposure, less atomic oxygen concentration) shows that a silicone overcoat renders even better protection for the atomic oxygen exposure.

TABLE 1
I–V data before and after Ar—O₂ plasma test.

| | | | I–V Characteristic | | | | | % Change = (after − before)/before (%) | | | |
|---|---|---|---|---|---|---|---|---|---|---|---|
| Cell# 30MW | Encapsulant | Plasma Test | Pmax | Jsc | Voc | ff | Rs | Pmax | Jsc | Voc | ff |
| 1241013507 | No | before | 8.72 | 6.74 | 2.168 | 0.597 | 78.3 | −54.36% | −8.61% | −16.70% | −40.03% |
| 1241013507 | | after | 3.98 | 6.16 | 1.806 | 0.358 | 161 | | | | |
| 1241013508 | No | before | 8.89 | 6.8 | 2.171 | 0.602 | 64.4 | −69.18% | −10.15% | −31.18% | −50.17% |
| 1241013508 | | after | 2.74 | 6.11 | 1.494 | 0.3 | 134 | | | | |
| 1241014501 | R&D HC | before | 8.71 | 6.62 | 2.164 | 0.608 | 64 | −86.45% | −20.09% | −58.83% | −58.72% |
| 1241014501 | | after | 1.18 | 5.29 | 0.891 | 0.251 | 169 | | | | |
| 1241033865 | R&D HC | before | 7.92 | 6.48 | 2.152 | 0.568 | 78.4 | −10.98% | −1.54% | −1.95% | −7.75% |
| 1241033865 | | after | 7.05 | 6.38 | 2.11 | 0.524 | 124 | | | | |
| 1243024671 | HC | before | 7.99 | 6.7 | 2.123 | 0.562 | 80 | −5.51% | −1.79% | −2.45% | −1.42% |
| 1243024671 | | after | 7.55 | 6.58 | 2.071 | 0.554 | 59.6 | | | | |
| 1243024672 | HC | before | 8.25 | 6.8 | 2.114 | 0.574 | 63.2 | −8.85% | −2.35% | −2.70% | −4.18% |
| 1243024672 | | after | 7.52 | 6.64 | 2.057 | 0.55 | 76.6 | | | | |
| 1282014501 | VPP | before | 8.62 | 6.81 | 2.122 | 0.596 | 76.2 | −0.81% | −0.88% | −0.75% | 1.01% |
| 1282014501 | | after | 8.55 | 6.75 | 2.106 | 0.602 | 52.8 | | | | |
| 1282026507 | SiOx | before | 7.65 | 6.78 | 2.104 | 0.536 | 95 | −10.07% | −1.92% | −5.66% | −2.80% |
| 1282026507 | | after | 6.88 | 6.65 | 1.985 | 0.521 | 52.1 | | | | |
| 1282037509 | SiOx | before | 9.17 | 6.86 | 2.146 | 0.623 | 71.3 | −87.79% | −10.35% | −67.10% | −58.43% |
| 1282037509 | | after | 1.12 | 6.15 | 0.706 | 0.259 | 152 | | | | |
| 1282049509 | VPP | before | 9.08 | 6.87 | 2.171 | 0.609 | 53.4 | −0.77% | −0.87% | −0.18% | 0.16% |
| 1282049509 | | after | 9.01 | 6.81 | 2.167 | 0.61 | 45.9 | | | | |

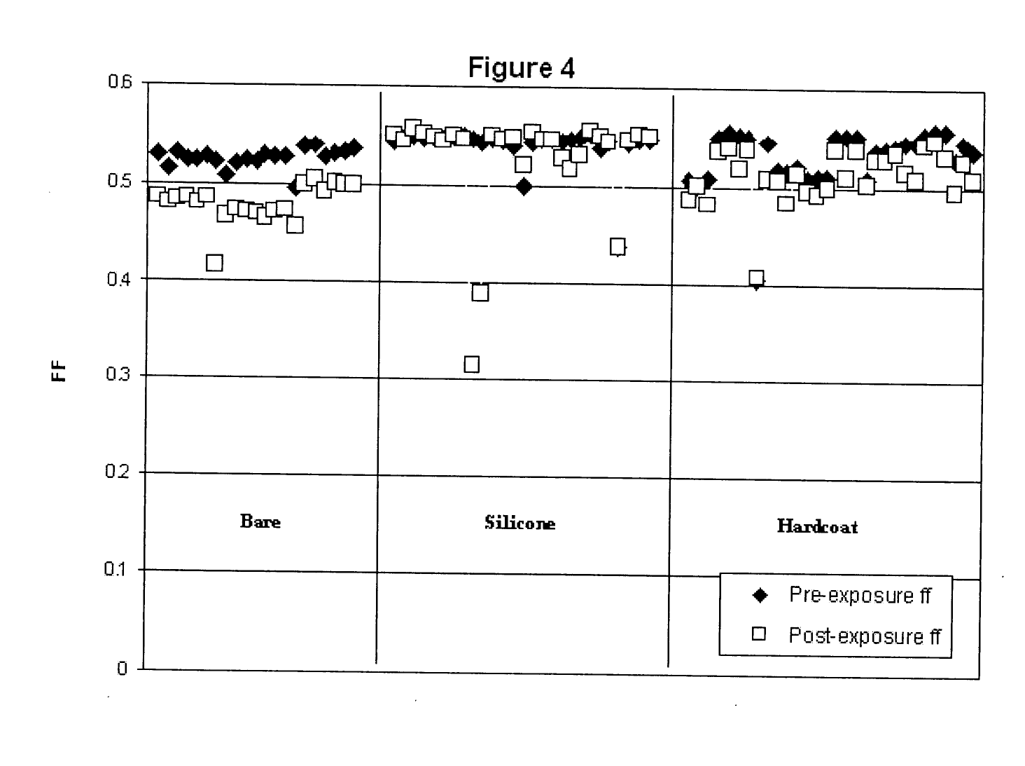

After these initial results, NASA Glenn Research Center was contracted for a more controlled atomic oxygen exposure test, because the atomic oxygen flux used for the in-house atomic oxygen test was unknown. NASA Glenn Research Center performed a controlled AO exposure test on the silicone coating. In this test, AO flux was determined prior to running the samples by placing Kapton witness coupons in various positions on the sample holder. By knowing the flux of the apparatus, the approximate operating time could be determined for a specified fluence level. Twenty six solar cell test samples were exposed in two separate AO tests. In the first case, fifteen samples (5 of each type of bare uncoated reference, silicone coating, and acrylic hardcoat coated cells) were placed on the sample holder along with a Kapton witness coupon. The exposure time was 35 hours and the fluence level was 4.3×10²⁰±4.3×10¹⁹ atoms/cm². In the second case, eleven samples and a Kapton witness coupon were exposed for 35 hours and fluence level of 4.1×10²⁰±4.0×10¹⁹ atoms/cm². It should be noted that the effective AO dose on a solar facing surface of the International Space Station in one year is about 4.6×10₂₀ atoms/cm². Solar cell I-V characteristics were measured before and after the test. Only the acrylic hardcoat samples were visually damaged after the test. Part of the hardcoat material seemed to have been removed, the sample surface was roughened, and the coating looked discontinuous. Bare and silicone coated cells did not show any visual change. The change in FF of the three sets of samples is shown in FIG. 4. After removing the obvious outliers, it is clear that the silicone coat protects the cells adequately. The bare and hardcoat samples exhibit some degradation. Table 2 summarizes the change in the average I-V results, before and, after the test, of all the samples for the three different coating conditions. The table shows that for the silicone coating, the changes in I-V parameters are within limits of measurement error. The I-V characteristics for the bare and the hardcoat cases show degradation in fill factor after the test. In conclusion, the silicone coating survived atomic oxygen exposure equivalent to about one year exposure under International Space Station environment. It showed no visual or I-V degradation after the AO exposure.

TABLE 2
Average change in I–V characteristics after the AO test

| Coating | Pmax | Jsc | Voc | FF | Rs |
|---|---|---|---|---|---|
| Bare | −8.68% | −0.27% | −0.16% | −8.27% | 17.93% |
| Silicone | −0.78% | −1.03% | 0.08% | 0.16% | 2.13% |
| Hardcoat | −0.92% | 2.47% | 0.06% | −3.37% | 6.36% |

### Adhesion

A basic Scotch tape test was used for evaluating the adhesion of the encapsulant coating on the solar cell. The procedure consists of: (1) applying a piece of clean cellophane tape onto the encapsulant coating and after it adheres well, (2) removing the tape from one end and inspecting for signs of delamination. All the encapsulants that adhere initially have passed this test.

### Damp Heat Test

A commercial damp heat test chamber was used for this test. The cells were originally tested at 50° C. and 85% relative humidity. The test lasted for a month although samples were taken out for measurements on a weekly basis. Since only very minor effect was seen when the cells were tested at 50° C. and 85% relative humidity, they were also tested at 85° C. and 85% relative humidity. The test results for both conditions on AMO cells only are summarized below.

### Test 1. Damp Heat at 50° C. 85% Relative Humidity

Encapsulants tested included: a) cells having a 30 nm SiOₓ coating; b) cells having a 60 nm SiOₓ, c) bare samples without any encapsulant coating, and d) samples with acrylic hardcoat. There were 10 H-strips in each group.

### Visual Appearance

The bare, 30 nm and 60 nm SiOₓ coated samples show some signs of delamination/corrosion on several pieces. The acrylic hardcoat samples did not show any noticeable change except that after four weeks, one cell had a small delaminated region about 1 mm wide along one exposed edge of the cell.

### I-V Measurement

I-V measurement under a solar simulator did not significantly separate any particular group from the others. The I-V parameters did not seem to change for any group before and after the damp heat. The average Pₘₐₓ dropped 3.5%, 2.7%, 1.3% and 1.1% for the 30 nm SiOₓ, 60 nm SiOₓ, bare, and acrylic hardcoat samples, respectively. The loss for the acrylic hardcoat samples is less than 1% Pₘₐₓ (if one delaminated cell is excluded from the data). The loss (3.5%) for the 30 nm SiOₓ coated case is greater than that for the bare samples. The results show that within limits of experimental error, the bare and the encapsulated samples do not exhibit any degradation in power output after the test.

### Test 2. Damp Heat at 85° C. 85% Relative Humidity

In this test, 11 H-strips of VPP encapsulated cells, 11 H-strips of SiOₓ coated cells, 22 H-strips of acrylic hardcoat cells, and 28 H-strips of silicone-encapsulated samples were tested and 12 bare H-strips were used as reference.

### Visual Inspection

Delamination spots appeared on VPP coated cells after the first week in the damp heat chamber. Smaller delamination spots were also found on bare and SiOₓ coated cells. Silicone-based overcoat and acrylic hardcoat seemed to protect the cells from delamination for three weeks. However, after two additional weeks of exposure in the 85/85 damp heat condition with reverse bias at −1.25V, delamination spots were also visible on a few hardcoat and silicone overcoat encapsulated cells. It should be noted that the total application time for the reverse bias is unknown due to experimental problems of applying continuous bias.

### I-V Measurement

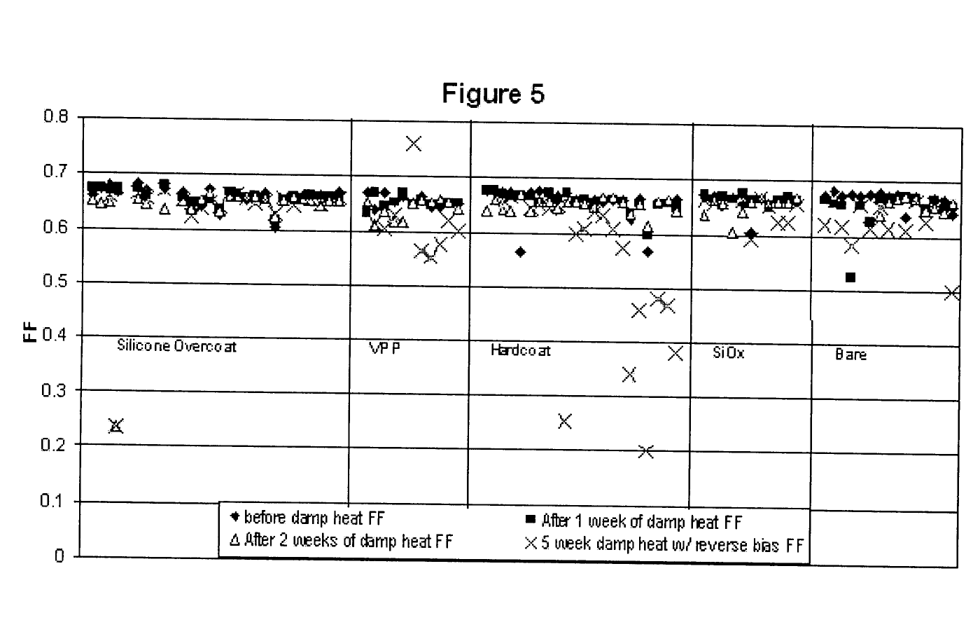

I-V measurements were made under a solar simulator before and after encapsulant coating. The measurements were repeated after the first, second, and fifth week of damp heat exposure. The V_{∝} and I_{sc} of most cells did not change significantly. The final FF as shown in FIG. 5, shows degradation for VPP, hardcoat, SiOₓ, and bare cells after 5 weeks of damp heat exposure (the last two weeks with inconsistent reverse bias at −1.25V). There is only a slight drop in the FF for the silicone-based overcoat encapsulated cells, indicating that silicone overcoat rendered better protection to solar cells under damp heat condition. As a group, FF of bare, SiOₓ, VPP, silicone overcoat, and hardcoat samples decreased by 6.3%, 1.9%, 5.8%, 1.4% and 5.3% respectively, as listed in Table 3. Silicone based overcoat seemed to perform the best among the encapsulants tested.

TABLE 3
Summary of damp heat test at 85° C., 85% RH for 5 Weeks.

| Encapsulant | Appearance | AM1.5 ΔFF(loss) |
|---|---|---|
| Bare Cell | Some delamination | 6.3% |
| SiOₓ | Some delamination | 1.9% |
| VPP | Some delamination | 5.8% |
| Silicone Overcoat | OK* | 1.4% |
| Hardcoat | OK* | 5.3% |

*No delamination visible in first three weeks, some delamination seen after 5 weeks.

### Reverse Bias Damp Heat Test at 85° C. 85% Relative Humidity

For this test, 6 bare H-strips and 6 encapsulated H-strips using silicone overcoat, were used. Table 4 summarizes the I-V data for all samples after one week of reverse bias test at −1.25V in damp heat at 85° C., 85% relative humidity.

TABLE 4
I–V after reverse bias damp heat test at −1.25 V, 1 week, 85° C., 85% RH.

| | | | | | | 1 Week Damp Heat | | | | | | | |
|---|---|---|---|---|---|---|---|---|---|---|---|---|---|
| | | After Coating | | | | w/ Reverse Bias | | | | Difference | | | |
| | | V_{oc} | Jsc | | Pₘₐₓ | V_{oc} | Jsc | | Pₘₐₓ | V_{oc} | Jsc | FF | Pₘₐₓ |
| | Run# 5MW1749 | (V) | (mA/cm²) | FF | (W) | (V) | (mA/cm²) | FF | (W) | Δ % | Δ % | Δ % | Δ % |
| Silicone Overcoat | 1034H1 | 2.230 | 5.434 | 0.661 | 1.040 | 2.221 | 5.795 | 0.660 | 1.107 | −0.39 | 6.65 | −0.20 | 6.48 |
| | 1034H2 | 2.230 | 5.716 | 0.659 | 1.100 | 2.227 | 5.861 | 0.653 | 1.110 | −0.15 | 2.52 | −0.98 | 0.94 |
| | 1034H3 | 2.230 | 5.696 | 0.667 | 1.110 | 2.227 | 5.921 | 0.658 | 1.131 | −0.14 | 3.96 | −1.37 | 1.91 |
| | 1034H4 | 2.240 | 5.784 | 0.657 | 1.110 | 2.228 | 5.935 | 0.661 | 1.141 | −0.53 | 2.62 | 0.67 | 2.76 |
| | 1034H5 | 2.230 | 5.712 | 0.660 | 1.100 | 2.226 | 5.852 | 0.658 | 1.118 | −0.20 | 2.44 | −0.27 | 1.62 |
| | 1034H6 | 2.230 | 5.591 | 0.655 | 1.070 | 2.220 | 5.689 | 0.655 | 1.079 | −0.43 | 1.74 | 0.01 | 0.83 |
| Bare | 1067H1 | 2.210 | 5.315 | 0.648 | 0.995 | 2.165 | 5.571 | 0.528 | 0.831 | −2.05 | 4.81 | −18.46 | −16.49 |
| | 1067H2 | 2.220 | 5.290 | 0.670 | 1.020 | 2.188 | 5.600 | 0.556 | 0.888 | −1.45 | 5.86 | −17.00 | −12.90 |
| | 1067H3 | 2.220 | 5.324 | 0.668 | 1.030 | 2.189 | 5.543 | 0.597 | 0.944 | −1.39 | 4.10 | −10.70 | −8.36 |
| | 1067H4 | 2.220 | 5.347 | 0.657 | 1.010 | 2.204 | 5.531 | 0.627 | 0.997 | −0.70 | 3.44 | −4.56 | −1.29 |
| | 1067H5 | 2.210 | 5.349 | 0.651 | 1.010 | 2.183 | 5.570 | 0.569 | 0.902 | −1.22 | 4.14 | −12.66 | −10.74 |
| | 1067H6 | 2.210 | 5.255 | 0.623 | 1.020 | 2.168 | 5.555 | 0.542 | 0.851 | −1.92 | 5.70 | −13.05 | −16.62 |

Table 5 gives the average V_{∝} and FF loss for the two groups. The I-V characteristics of all bare samples degraded significantly: average V_{∝} by 1.5% and average FF by 12.7%. The silicone overcoat encapsulated cells suffered very little losses: V_{∝} by only 0.3% and FF by 0.4%

TABLE 5
Average Voc and FF loss computed from Table 4 for the two groups.

| Encapsulant | Appearance | AM1.5 Δ V_{oc} (loss) | AM1.5 Δ FF (loss) |
|---|---|---|---|
| Bare Cell | Some | 1.5% | 12.7% |
| | Delamination | | |
| Silicone | OK | 0.3% | 0.4% |
| Overcoat | | | |

### Thermal Cycling

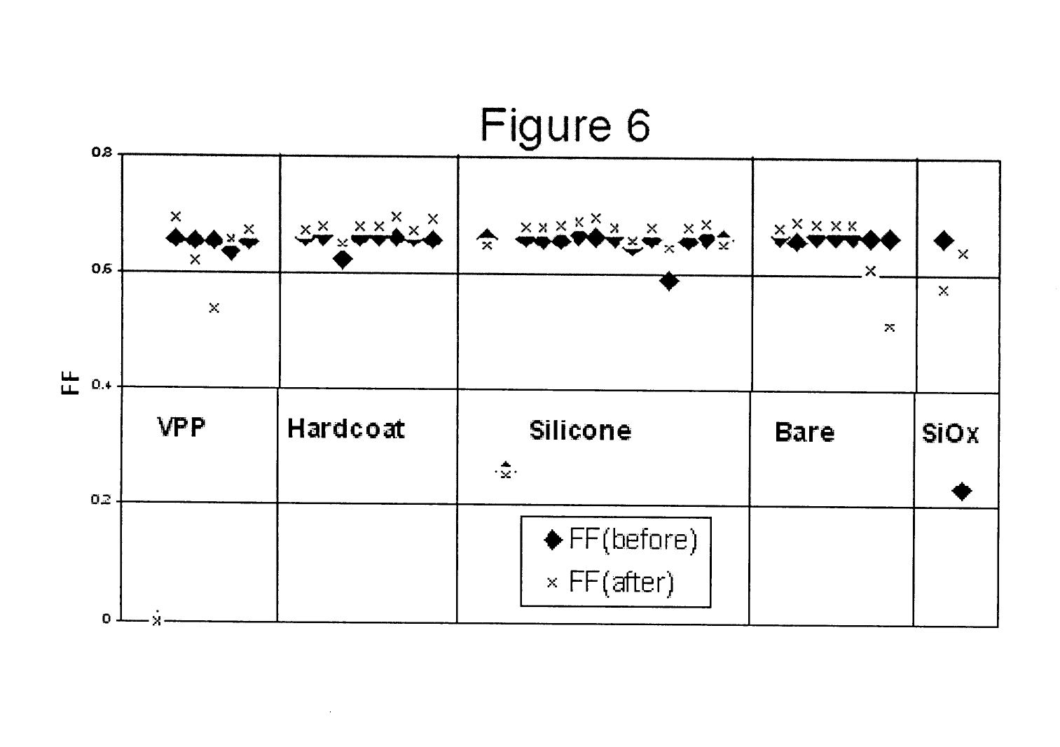

Commercially available standard thermal cycling equipment was used for this test. As per NASA requirement, this test was conducted from −175° C. to 100° C. in a nitrogen environment. The test was conducted for 1000 cycles. Table 6 shows I-V characteristics before and after the 1000 cycles of thermal cycle test. It is clear that after removing obvious outliers (likely due to repetitive handling), there is no significant change after the thermal cycle test for any of the encapsulant materials. FIG. 6 shows FF change before and after the thermal cycling test. It is clear that no significant change occurred during thermal cycling.

TABLE 6
I–V measurement before and after 1000 thermal cycles from −175° C. to 100° C.

| | Sample # | Before TC | | | | After 1000 cycles | | | | Difference | | | |
|---|---|---|---|---|---|---|---|---|---|---|---|---|---|
| Coating | 5MW1749 | Voc | Jsc | FF | Pmax | Voc | Jsc | FF | Pmax | Voc | Jsc | FF | Pmax |
| VPP | 1039H2 | 2.22 | 5.76 | 0.656 | 1.093 | 2.23 | 5.46 | 0.694 | 1.104 | 0.73% | −5.48% | 5.40% | 0.95% |
| | 1039H3 | 2.22 | 5.73 | 0.654 | 1.085 | 2.21 | 5.61 | 0.619 | 1.001 | −0.33% | −2.13% | −5.73% | −8.34% |
| | 1039H4 | 2.21 | 5.68 | 0.654 | 1.073 | 2.17 | 5.68 | 0.536 | 0.862 | −1.90% | −0.05% | −22.04% | −24.43% |
| | 1039H5 | 2.20 | 5.61 | 0.634 | 1.018 | 2.22 | 5.44 | 0.659 | 1.037 | 0.94% | −3.02% | 3.81% | 1.83% |
| | 1039H6 | 2.20 | 5.48 | 0.656 | 1.030 | 2.22 | 5.35 | 0.675 | 1.046 | 1.04% | −2.47% | 2.88% | 1.52% |
| Hardcoat | 1042H1 | 2.21 | 5.60 | 0.659 | 1.064 | 2.23 | 5.37 | 0.673 | 1.051 | 1.06% | −4.44% | 2.02% | −1.25% |
| | 1042H2 | 2.21 | 5.56 | 0.664 | 1.065 | 2.23 | 5.31 | 0.679 | 1.050 | 1.02% | −4.80% | 2.27% | −1.37% |
| | 1042H3 | 2.20 | 5.68 | 0.621 | 1.013 | 2.23 | 5.42 | 0.651 | 1.024 | 1.08% | −4.82% | 4.64% | 1.12% |
| | 1042H4 | 2.21 | 5.65 | 0.662 | 1.080 | 2.24 | 5.41 | 0.681 | 1.075 | 1.10% | −4.42% | 2.71% | −0.48% |
| | 1042H5 | 2.21 | 5.65 | 0.664 | 1.081 | 2.23 | 5.44 | 0.679 | 1.074 | 0.94% | −3.93% | 2.18% | −0.72% |
| | 1042H6 | 2.21 | 5.63 | 0.662 | 1.075 | 2.23 | 5.35 | 0.697 | 1.083 | 0.86% | −5.34% | 5.00% | 0.78% |
| | 1044H1 | 2.20 | 5.50 | 0.661 | 1.045 | 2.23 | 5.32 | 0.673 | 1.040 | 0.98% | −3.35% | 1.85% | −0.44% |
| | 1044H2 | 2.21 | 5.65 | 0.658 | 1.073 | 2.23 | 5.26 | 0.695 | 1.064 | 0.83% | −7.35% | 5.23% | −0.89% |
| Silicone | 1044H4 | 2.22 | 5.65 | 0.662 | 1.083 | 2.22 | 5.51 | 0.648 | 1.036 | 0.04% | −2.41% | −2.09% | −4.50% |
| | 1046H1 | 2.21 | 5.52 | 0.660 | 1.050 | 2.23 | 5.35 | 0.679 | 1.058 | 0.91% | −3.12% | 2.82% | 0.69% |
| | 1046H2 | 2.22 | 5.58 | 0.657 | 1.059 | 2.22 | 5.38 | 0.679 | 1.060 | 0.31% | −3.55% | 3.22% | 0.09% |
| | 1046H3 | 2.21 | 5.58 | 0.659 | 1.061 | 2.24 | 5.32 | 0.683 | 1.059 | 1.05% | −5.04% | 3.60% | −0.19% |
| | 1046H4 | 2.21 | 5.49 | 0.666 | 1.055 | 2.23 | 5.25 | 0.690 | 1.053 | 0.71% | −4.55% | 3.50% | −0.17% |
| | 1046H5 | 2.21 | 5.46 | 0.665 | 1.049 | 2.23 | 5.20 | 0.696 | 1.054 | 0.69% | −4.98% | 4.52% | 0.45% |
| | 1046H6 | 2.22 | 5.49 | 0.664 | 1.055 | 2.23 | 5.30 | 0.679 | 1.047 | 0.61% | −3.66% | 2.22% | −0.74% |
| | 1048H1 | 2.21 | 5.59 | 0.647 | 1.043 | 2.23 | 5.37 | 0.656 | 1.024 | 0.73% | −4.11% | 1.48% | −1.82% |
| | 1048H2 | 2.22 | 5.63 | 0.661 | 1.080 | 2.24 | 5.43 | 0.681 | 1.080 | 0.72% | −3.75% | 2.92% | 0.00% |
| | 1048H3 | 2.19 | 5.77 | 0.590 | 0.974 | 2.22 | 5.51 | 0.646 | 1.031 | 1.23% | −4.86% | 8.75% | 5.49% |
| | 1048H4 | 2.22 | 5.69 | 0.659 | 1.088 | 2.24 | 5.46 | 0.680 | 1.085 | 0.79% | −4.27% | 3.10% | −0.24% |
| | 1048H5 | 2.22 | 5.65 | 0.663 | 1.087 | 2.24 | 5.41 | 0.685 | 1.084 | 0.75% | −4.36% | 3.16% | −0.30% |
| | 1048H6 | 2.22 | 5.65 | 0.660 | 1.079 | 2.35 | 5.40 | 0.650 | 1.077 | 5.81% | −4.72% | −1.49% | −0.11% |
| Bare | 1044H3 | 2.24 | 5.82 | 0.668 | 1.133 | 2.24 | 5.60 | 0.681 | 1.115 | 0.31% | −3.93% | 1.92% | −1.61% |
| | 1044H6 | 2.24 | 5.81 | 0.658 | 1.114 | 2.24 | 5.56 | 0.691 | 1.124 | 0.26% | −4.34% | 4.80% | 0.93% |
| | 1051H2 | 2.24 | 5.72 | 0.666 | 1.113 | 2.25 | 5.48 | 0.686 | 1.103 | 0.47% | −4.40% | 2.84% | −0.96% |
| | 1051H3 | 2.24 | 5.77 | 0.667 | 1.123 | 2.25 | 5.50 | 0.688 | 1.111 | 0.59% | −4.88% | 3.00% | −1.13% |
| | 1051H4 | 2.24 | 5.75 | 0.668 | 1.122 | 2.25 | 5.53 | 0.688 | 1.118 | 0.54% | −3.85% | 2.86% | −0.34% |
| | 1051H5 | 2.24 | 5.75 | 0.663 | 1.112 | 2.21 | 5.60 | 0.608 | 0.983 | −1.09% | −2.62% | −9.02% | −13.09% |
| | 1051H6 | 2.23 | 5.70 | 0.663 | 1.101 | 2.16 | 5.61 | 0.510 | 0.807 | −3.41% | −1.47% | −29.99% | −36.40% |
| SiOx | 1043H5 | 2.24 | 5.82 | 0.662 | 1.127 | 2.21 | 5.65 | 0.577 | 0.938 | −1.52% | −3.09% | −14.80% | −20.15% |

### Thermal Stability at High Temperature

Samples were placed overnight in an oven preset at 125° C., after which the I-V characteristic of the test samples was measured to compare with the performance before the test. Tests showed no significant loss in electrical performance for any encapsulants.

### Outgassing

Outgassing tests at two sets of parameters were carried out in-house: (1) using an oven at 150° C. at atmospheric pressure; and (2) in vacuum at room temperature. These tests show that baking causes the silicone-based overcoat to outgas initially but this stops in a few hours. All encapsulants investigated pass the outgassing test with less than 1% total weight loss. An outgassing test system for measuring the total mass loss (TML) per ASTM standard ASTM-E-595-93 (1999): outgassing in high vacuum chamber (better than 5×10⁻⁵Torr) at high temperature (125° C.) for 24 hours was built. The equipment was used to optimize the deposition and curing parameters of the silicone-based encapsulant in order to reduce the TML. All of the tested coatings, including the inventive silicone encapsulant pass the ASTM TML requirement.

### Pin-Hole Free Test

In order to provide complete protection to the underlying cell, the encapsulant coating must be coherent and pinhole free. For this test, a layer of ITO (indium tin oxide) is deposited on top of the encapsulant, and the electrical resistance measured between the top ITO layer and the ITO layer of the solar cell underneath the encapsulant is used to quantify if the sample is pin-hole free. If there are pinholes in the encapsulant layer, the ITO would short through to the ITO underneath the encapsulant, and therefore, electrical resistance between the two ITO layers is a direct measure for this test. A high resistance implies a pinhole free encapsulant layer. The hardcoat samples, silicone and VPP encapsulants all pass the test.

### UV Exposure Test

It is known that there is VUV (<200 nm) and NUV (200 nm to 400 nm) in space. Although VUV is greatly reduced at airship altitude, there is still substantial amount of NUV irradiation. The encapsulants must withstand the UV irradiation without significant darkening or physical damages. NASA Glenn Research Center performed tests for both VUV and NUV. A total of 27 QA/QC cells were encapsulated with different coatings including SiOₓ, VPP, acrylic hardcoat and silicone overcoat spray coatings. Of the 27 samples, 20 were exposed to VUV and 7 to NUV at NASA for 1 week (equivalent to 3300 ESH (equivalent sun hours) for VUV and 740 ESH for NUV). Quantum efficiency (Q), optical reflection (R), and I-V were measured before and after UV exposure.

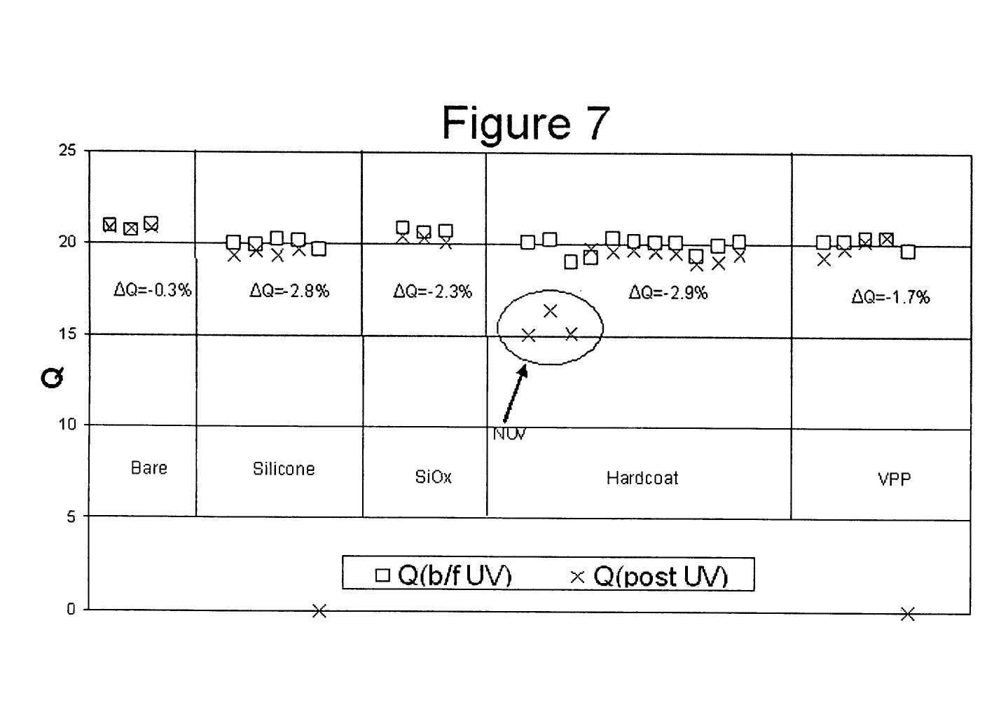

After 3300 ESH for VUV and 740 ESH for NUV exposure, it is found that all three acrylic hardcoat samples visually darkened under NUV, total quantum efficiency Q and J_{sc} of the cells dropped by about 20%. The quantum efficiency Q loss of the other encapsulants ranged from 2-3%. The acrylic samples, however, did not change much on exposure to VUV. FIG. 7 shows the total integrated Q values before and after the UV exposure. The Q of bare samples showed only a small decrease. The average Q of the silicone overcoat, SiOₓ, hardcoat (excluding 3 darkened ones), and VPP encapsulated samples degraded by 2.8%, 2.3%, 2.9% and 1.7% respectively, as listed in Table 8. The acrylic hardcoat does not seem to be stable under space NUV. Other encapsulants seem to be fine.

TABLE 8
Average Q Loss After VUV/NUV Exposure for Different Encapsulants.

| Cell | Bare | Silicone | SiOₓ | Hardcoat | VPP |
|---|---|---|---|---|---|
| Q loss | 0.3% | 2.8% | 2.3% | 2.9% | 1.7% |

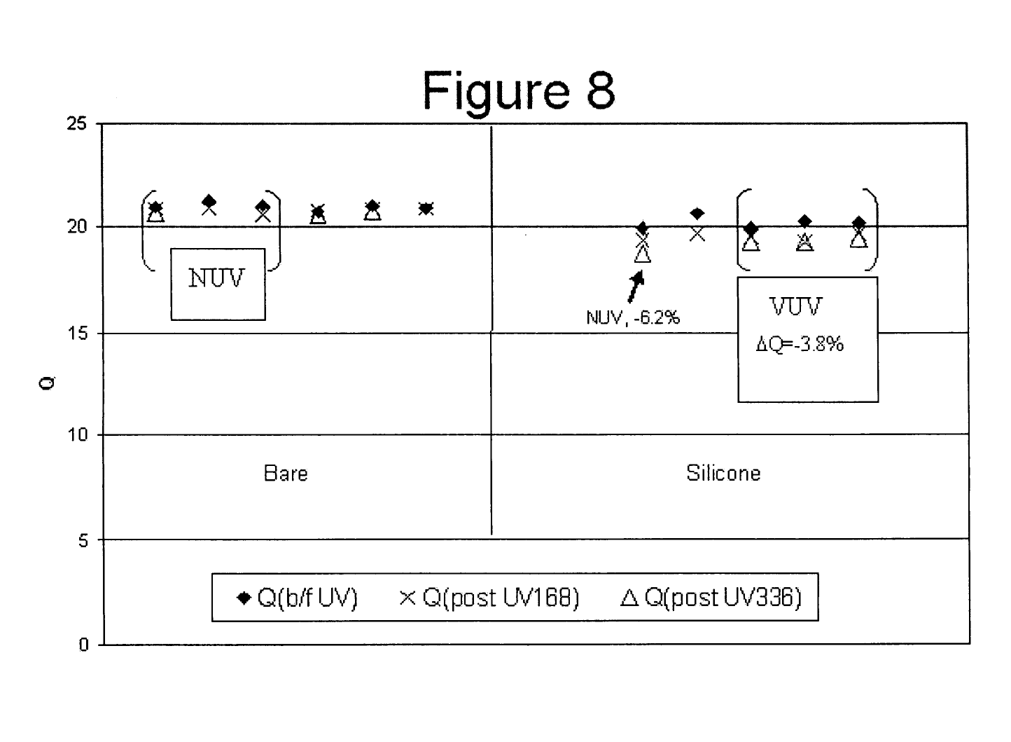

In additional testing, five small-area triple-junction QA/QC cells (3 bare and 2 with silicone coating) were exposed to NUV. Six additional samples (3 bare and 3 with silicone coating) were exposed to VUV. The UV intensity in Equivalent Sun Hours (ESH) were 3300 ESH for VUV and 740 ESH for NUV during the first test described above. For the additional test, the VUV exposure was equivalent to 620 ESH and NUV was 592 ESH. Measurements of the Q, R, and I-V characteristics of the cells were measured before and after UV exposure. FIG. 8 shows the total integrated Q before and after the UV exposure for the two different coatings. FIG. 8 shows that: a) there was a very small decease in Q of the bare samples; b) the average Q of the silicone coated cells dropped by 3.8%, and c) the Q of one cell with silicone coating decreased by 6.2% under NUV. The reason for the decease of 6.2% in Q of the one silicone-coated cell for the NUV exposure case is not understood. According to a few independent sources, silicone material has been safely used in space applications and according to its manufacturer, any potential degradation should lead to higher transparency and, therefore, higher Q. The inventors speculate that the sample was damaged mechanically due to repetitive handling during the test sequence.

In order to evaluate if the silicone coating will withstand stratospheric environment at an altitude of about 20 km, the solar UV spectrum at that altitude and the silicone absorption in the same wavelength range were plotted. The plot showed that silicone has an absorption band in the wavelength range of about 220-270 nm. However, there is negligible UV content in that wavelength range. There is a small UV peak in the wavelength range of about 195-210 nm in the solar spectrum but silicone does not absorb in that range. Therefore, it can be deduced that irrespective of the NASA NUV results, the silicone coat protects the cells adequately for stratospheric application. To confirm this, an in-house UV testing facility was set up to conduct more tests in simulated stratospheric UV exposure condition. The test facility was shown to have plenty of radiation in the wavelength range 280-500 nm.

Table 9 lists Q measurements of cells before and after 288 hours of UV exposure. In test, UV intensity was set to ˜5 suns, as measured by integrated power intensity over the spectrum region. It is clear that the coated cells exhibit a behavior similar to that of the bare reference cells. There is negligible change in the green and red regions of the spectrum. In the blue range, the Q decreases by only about 1%, which may be attributed to light-induced Staebler-Wronski degradation. Thus, the coating is stable under the UV test.

TABLE 9
Q measurement of cells before/after 288 hours of UV exposure under 5 suns.

| UV exposure condition: 280–400 nm, 5 sun intensity | | | | | | | | | | Q loss 288 hours (%) | | | |
|---|---|---|---|---|---|---|---|---|---|---|---|---|---|
| Sample # | Type | Blue | Green | Red | Q (Tot.) | Blue | Green | Red | Q (Tot.) | Blue | Green | Red | Q (Tot.) |
| 1914-9150-10 | Silicone | 6.23 | 6.54 | 7.60 | 20.37 | 6.14 | 6.49 | 7.56 | 20.19 | 1.44% | 0.76% | 0.53% | 0.88% |
| 1914-2950-5 | | 6.22 | 6.74 | 7.60 | 20.56 | 6.16 | 6.77 | 7.63 | 20.56 | 0.96% | −0.45% | −0.39% | 0.00% |
| 128200450-06 | | 6.31 | 6.76 | 7.12 | 20.19 | 6.28 | 6.72 | 7.19 | 20.19 | 0.48% | 0.59% | −0.98% | 0.00% |
| 1914-2750-6 | Bare | 6.12 | 7.09 | 7.91 | 21.12 | 6.09 | 7.01 | 7.90 | 21.00 | 0.49% | 1.13% | 0.13% | 0.57% |
| 1914-2750-7 | | 6.13 | 7.13 | 7.93 | 21.19 | 6.03 | 7.03 | 7.85 | 20.91 | 1.63% | 1.40% | 1.01% | 1.32% |
| 1914-2750-5 | | 6.19 | 7.02 | 7.92 | 21.13 | 6.15 | 7.04 | 7.87 | 21.06 | 0.65% | −0.28% | 0.63% | 0.33% |

Table 10 lists Q measurements of cells before and after two UV exposure times at an elevated UV intensity about 9.4 suns. The first measurement was done after 187 hours and then continued to 376 hours for the second measurement. Once again, the reduction in Q after the two exposure times at the elevated intensity is negligible compared to the bare cells. This result confirms the result that the coating is stable under the UV exposure. Thus, the silicone coating shows no noticeable degradation under the stratospheric UV condition.

TABLE 10
Q measurements of cells before and after UV exposure under 9.4 suns.

| | | b/IUV | | | | UV 187 hours | | | | UV 376 hours | | | |
|---|---|---|---|---|---|---|---|---|---|---|---|---|---|
| Sample # | Type | Blue | Green | Red | Q (Total) | Blue | Green | Red | Q (Total) | Blue | Green | Red | Q (Total) |
| 1914-4250-8 | Silicone | 6.25 | 6.67 | 7.61 | 20.53 | 6.21 | 6.61 | 7.59 | 20.41 | 6.13 | 6.56 | 7.47 | 20.16 |
| | Q loss(%) | | | | | 0.64% | 0.90% | 0.26% | 0.58% | 1.92% | 1.65% | 1.84% | 1.80% |
| 1240-150-10 | Silicone | 6.39 | 6.16 | 6.62 | 19.17 | 6.29 | 5.98 | 6.46 | 18.73 | 6.33 | 5.92 | 6.35 | 18.60 |
| | Q loss(%) | | | | | 1.56% | 2.92% | 2.42% | 2.30% | 0.94% | 3.90% | 4.08% | 2.97% |
| 1914-9150-01 | Silicone | 6.15 | 6.81 | 7.4.6 | 20.42 | 6.05 | 6.66 | 7.39 | 20.10 | 6.05 | 6.68 | 7.40 | 20.13 |
| | Q loss(%) | | | | | 1.63% | 2.20% | 0.94% | 1.57% | 1.63% | 1.91% | 0.80% | 1.42% |
| 1914-8850-03 | Bare | 6.23 | 7.14 | 7.85 | 21.22 | 6.10 | 6.93 | 7.75 | 20.78 | 6.07 | 6.91 | 7.77 | 20.75 |
| | Q loss(%) | | | | | 2.09% | 2.94% | 1.27% | 2.07% | 2.57% | 3.22% | 1.02% | 2.21% |
| 1914-2750-08 | Bare | 6.11 | 7.11 | 7.93 | 21.15 | 5.97 | 6.93 | 7.82 | 20.72 | 5.98 | 6.95 | 7.82 | 20.75 |
| | Q loss(%) | | | | | 2.29% | 2.53% | 1.39% | 2.03% | 2.13% | 2.25% | 1.39% | 1.89% |
| 1914-0650-10 | Bare | 5.97 | 6.91 | 7.98 | 20.86 | 5.96 | 6.82 | 7.89 | 20.67 | 5.98 | 6.79 | 7.86 | 20.63 |
| | Q loss(%) | | | | | 0.17% | 1.30% | 1.13% | 0.91% | −0.17% | 1.74% | 1.50% | 1.10% |

### Ozone Exposure

This test is applicable to stratospheric application only. There exists substantial amount of ozone in the stratospheric environment. The ozone concentration at 20 km is about 7 ppm. Therefore, the encapsulant should withstand ozone in the environment. An in-house ozone testing system was built and concentrated ozone was produced using an ozone generator and then fed into a chamber. When the ozone concentration rose to the desired level, two shutoff valves for ozone input and exhaust are closed. The ozone concentration used for the test so far is about 1% which is considerably higher than the estimated 7 ppm found in the stratosphere. Samples were exposed to the ozone atmosphere for about 16 hours before they were visually examined and measured.

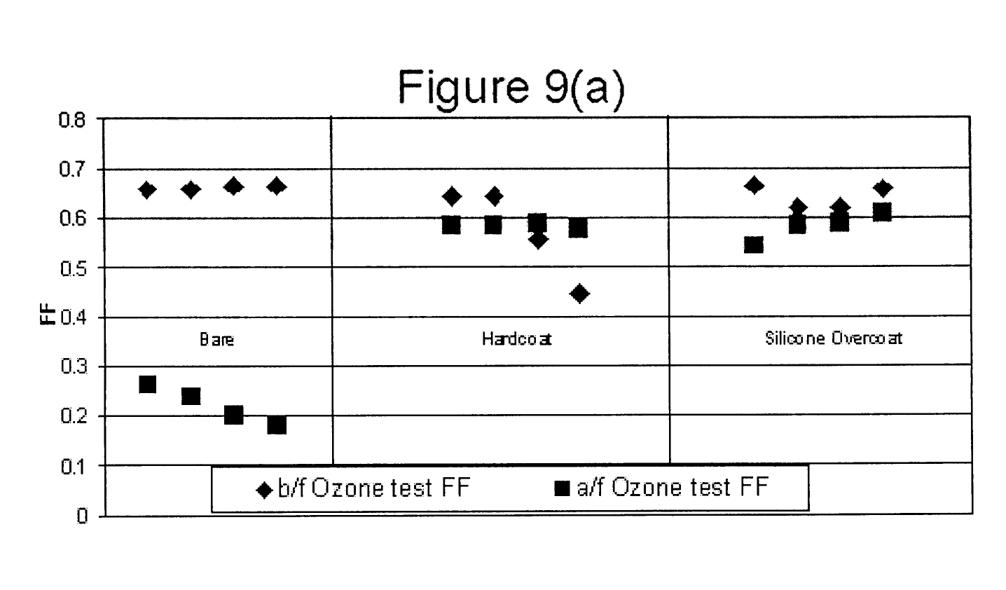

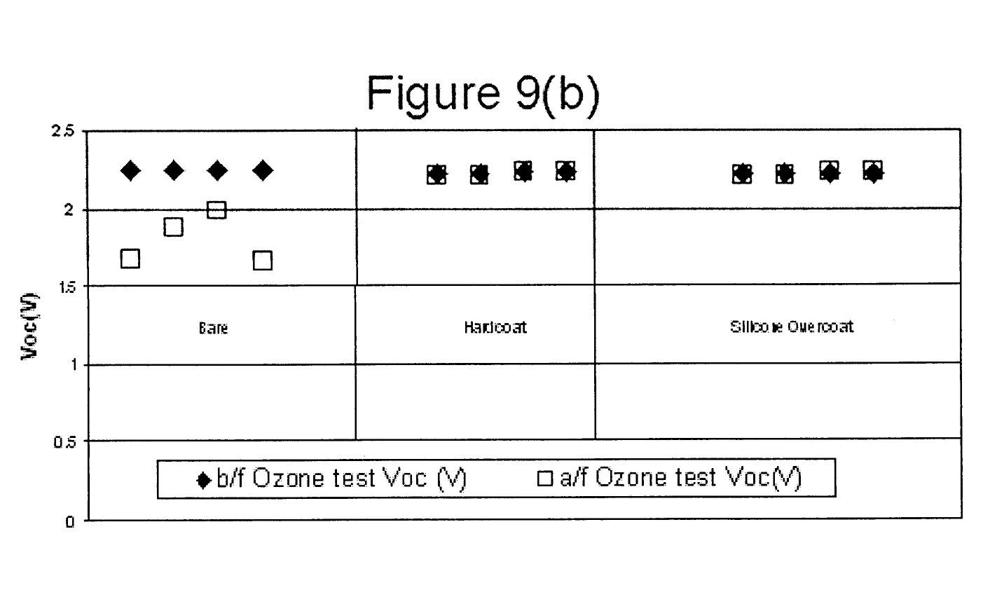

There was no visible effect after 16 hours exposure. However, after about 64 hours, it was found that the bare and 30 nm SiOₓ and 1 mm VPP coated samples exhibit discoloration. The discolored material delaminates readily when subjected to the cellophane tape adhesion test. The 0.2 mil silicone overcoat and acrylic hardcoat did not show any visible degradation. FIG. 9(a) shows test result of fill factor (FF) for ozone exposure of a few test cell samples. It is clear that the FF of the bare cells decreased by about 70% while both hardcoat and silicone overcoat cells held up fine. FIG. 9(b) shows the corresponding V_{∝} values for the three cases. The V_{∝} of both the hardcoat and silicone overcoat cells were essentially invariant as a result of the test but that of the bare samples degraded significantly. In summary, the bare, 30 nm SiOₓ, and 1 mm VPP coated samples failed the ozone exposure test, while the 0.2 mil silicone overcoat and acrylic hardcoat did not show any visible degradation after ozone exposure.

### Paschen Discharge

It is envisaged that in an actual space or stratospheric installation, the solar cell array will have individual cells located in close proximity. It is possible that two cells with very different electrical potentials will be arranged next to each other. Since separation between cells can be very close to the Paschen minimum, particularly at stratospheric altitude where the pressure is relatively high, precautions have to be taken to prevent arcing or Paschen discharge. A vacuum system was used for this test. Two solar cells were placed about 1 mm apart on a Teflon plate in the vacuum system. That is, their bus bars were positioned adjacent each other with a spacing of about 1 mm. The system was brought to a pressure of about 40 Torr to simulate stratospheric environment. The cells were then biased to 300V relative to each other. The electrical bias was applied for about 15 hours to evaluate if there would be any arcing. Solar cell performance was measured before and after the test. For the tests conducted with bias applied to both top and bottom of the cells, there was no evidence of arcing or cell degradation.

Other cells were biased relative to each other, slowly from 0V to about 700V or until arcing was observed. For tests conducted with bias applied to both top and bottom of the cells, we have not seen any arcing until the bias voltage reaches over 500V. This advises that if array voltage exceeds 500V, the cells should be spaced more than 1 mm apart.

### Electrostatic Discharge (ESD)

A cell on freestanding polymer substrate was subjected to an ESD test at NASA Glenn Research Center. The cell configuration was a triple-junction device deposited on a freestanding polymer substrate with 0.2 mil silicone coating. The cell passed the test. NASA GRC has carried out ESD tests of our silicone coated cells in a simulated LEO environment. A horizontal vacuum chamber equipped with a cryogenic pump provided a background pressure 0.3 μTorr. A xeon (Xe) plasma was generated by one Kaufman source. Plasma parameters are: floating potential −2 V; plasma potential 7 V, electron temperature 0.85 eV; electron number density 8E+5 1/cm3; neutral gas pressure 30 μTorr. Three groups of samples with coating thickness 1.5 mil, 0.2 mil, and bare reference cells, were mounted on a fiberglass plate. Current collections were measured for all samples before and after high voltage breakdown test. Each sweep from −100 V to +100 V was repeated for three times.

Only the bare reference samples show sharp increases in the current magnitude at about 80V (snapover effect) indicating heavy damage of the sample surface at high voltage. All silicone coated cells demonstrated high quality insulation, as confirmed by very low current collection. High voltage breakdown tests were conducted by biasing each sample to a power supply through an RC network (R=100 kΩ, C=1 μF). Negative voltage was gradually increased until a current pulse is registered. Time interval between voltage steps varied between 15 and 20 minutes. The breakdown voltage at various silicone thicknesses are shown in Table 11.

TABLE 11
Breakdown voltage of solar cells encapsulated by different
thickness of silicone

| Sample | Silicone Thickness | Breakdown Voltage | |
|---|---|---|---|
| Number | (mil.) | (V) | Comment |
| 103 | 0, bare reference | −600 | |
| 105 | 0, bare reference | −600 | |
| 1 | 0.2 | −150 | Surface flashing |
| 9 | 0.2 | −150 | Surface flashing |
| 4 | 1.5 | −250 | Surface flashing |
| 5 | 1.5 | −200 | |

It should be noted that the “surface flashing” observed is not common for other samples. Although they looked like short discharges, neither current nor voltage probes could detect any effect. We suspect that they may be caused by surface flashover surface discharge to plasma with no significant alteration in solar cells.

The results of the ESD tests show that silicone coated solar cells are suitable for use in LEO orbit with bus voltage below 150V, comparable to operating voltage of common international space stations and commercial communication satellites. The bus voltage limit can be increased as silicone thickness increases.

### Emissivity Test

The emissivity of the solar cells coated with the silicone based coating of the present invention has been measured as well as bare samples without any coating, acrylic hard coat, and silicon oxide coated cells. Samples on stainless steel substrates as well as KAPTON substrates were tested. The silicone coating of the present invention does increase emissivity of the coated sample significantly. Table 12 shows the results of the emissivity testing.

TABLE 12
Emissivity and Solar Absorptivity for coated samples

| | | | | Solar |
|---|---|---|---|---|
| Coating | Cell Substrate | Thickness (mil) | Emissivity | Absorptivity |
| Bare | Kapton | 0 | 0.49 | 0.68 |
| | Stainless Steel | 0 | 0.51 | 0.68 |
| Acrylic | Kapton | 0.33 | 0.70–0.81 | 0.71 |
| Hard | Stainless Steel | 0.25 | 0.57–0.73 | 0.68 |
| Coat | Stainless Steel | 0.35 | 0.60–0.74 | 0.68 |
| | Stainless Steel | 1.26 | 0.71–0.86 | 0.68 |
| Silicone | Kapton | 0.36 | 0.74 | 0.68 |
| Overcoat | Stainless Steel | 0.21 | 0.65–0.71 | 0.68 |
| | Stainless Steel | 0.63 | 0.72 | 0.68 |
| | Stainless Steel | 2.4 | 0.85 | 0.69 |
| SiOₓ | Kapton | 30 nm | 0.5 | 0.69 |
| | Stainless Steel | 30 nm | 0.51 | 0.68 |

Finally, Table 13 summarizes the results of most of the tests performed and clearly indicates that the silicone coating is the only one that passes all of the tests and therefore is the best choice for coating light weight stratospheric and outer space solar cells. Furthermore, while the silicone coating provides superb protection of the solar cells from the stratospheric environment and very good protection from the outer space environment, an additional layer of a transparent conductive material deposited over the silicone layer may provide additional protection in the outer space environment. That is, this additional layer may provide added protection from UV radiation as well as allow for leakage of electrostatic charge, helping prevent destructive ESD events. Examples of such transparent conductive layers include layers of indium-tin-oxide (ITO) or zinc oxide (ZnO).

TABLE 13
Summary of Test Results for Various Encapsulant Coatings.

| | | | Acrylic | | |
|---|---|---|---|---|---|
| Encapsulant | Silicone | VPP | Hardcoat | SiOₓ | Bare Cell |
| Adhesion | OK | OK | OK | OK | OK |
| Outgassing | OK | OK | OK | OK | OK |
| Thermal Cycling | OK | OK | OK | OK | OK |
| Optical | OK | OK | OK | OK | OK |
| Damp Heat | OK | Some | OK | Some | Some |
| | | Delamination | | Delamination | Delamination |
| Reverse Bias | OK | Fail | OK | Fail | Fail |
| Pin-Hole | OK | Fail | OK | Fail | Fail |
| VUV Radiation | OK | OK | OK | OK | OK |
| NUV Radiation | OK | OK | Darkened | OK | OK |
| Ozone | OK | Fail | OK | Fail | Fail |
| Atomic Oxygen | OK | OK | OK | Fail | Fail |

In view of the foregoing it is clear that the invention may be practiced in a variety of configurations different from those depicted and described herein. For example, the present invention could be used with solar cells other than amorphous silicon solar cells, such as, for example, crystalline silicon solar cells, gallium-arsenide solar cells, copper-indium-diselenide solar cells, copper-indium-gallium-diselenide solar cells, cadmium-tellurium solar cells, etc. All of such variations and modifications are within the scope of the invention. The foregoing drawings, discussions and descriptions are meant to be illustrative of particular embodiments of the invention and not meant to be limitations upon the practice thereof. It is the following claims, including all equivalents, which define the scope of the invention.

We claim:

1. A photovoltaic device adapted for use in a stratospheric or outer space environment, said photovoltaic device comprising:
a substrate;
at least one solar cell deposited on said substrate; and
a protective coating deposited over and completely encapsulating said at least one solar cell; wherein said protective coating:
a) does not deleteriously affect the photovoltaic properties of said at least one solar cell; and
b) is formed of a material which reduces the adverse effect of the harsh conditions in the stratospheric or outer space environment on the performance of the photovoltaic device.

2. The photovoltaic device of claim 1, wherein said protective also remains substantially unchanged when exposed to the harsh conditions in the stratospheric router space environment in which the photovoltaic device is adapted to be used.

3. The photovoltaic device of claim 1, wherein said protective coating comprises a layer of a silicone based material.

4. The photovoltaic device of claim 3, wherein said protective coating is a spray deposited coating of a silicone based material.

5. The photovoltaic device of claim 4, wherein said protective coating is between 0.01 and 2 mil thick.

6. The photovoltaic device of claim 5, wherein said protective coating is between 0.2 and 2 mil thick.

7. The photovoltaic device of claim 6, wherein said protective coating is between 0.5 and 2 mil thick.

8. The photovoltaic device of claim 7, wherein said protective coating is between 1 and 2 mil thick.

9. The photovoltaic device of claim 1, wherein said substrate comprises a thin web of metal or polymer.

10. The photovoltaic device of claim 9, wherein said substrate comprises a thin web of metal.

11. The photovoltaic device of claim 10, wherein said metal comprises stainless steel.

12. The photovoltaic device of claim 9, wherein said substrate comprises a thin web of polymer.

13. The photovoltaic device of claim 12, wherein said polymer comprises polyimide.

14. The photovoltaic device of claim 1, wherein said at least one solar cell comprises at least one amorphous silicon solar cell.

15. The photovoltaic device of claim 14, wherein said at least one solar cell comprises at least one triple junction amorphous silicon solar cell.

16. The photovoltaic device of claim 1, further comprising a back-reflecting structure disposed between said substrate and said at least one solar cell.

17. The photovoltaic device of claim 1, further comprising a top conducting layer disposed between said at least one solar cell and said protective coating.

18. The photovoltaic device of claim 17, wherein said top conducting layer comprises indium-tin-oxide (ITO).

19. The photovoltaic device of claim 18, further comprising a current collection grid disposed between said top conducting layer and said protective coating.

20. The photovoltaic device of claim 3, wherein said protective coating further includes a layer of a transparent conductive material deposited on top said layer of a silicone based material.

21. The photovoltaic device of claim 20, wherein said layer of a transparent conductive material comprises a layer of indium-tin-oxide.

22. The photovoltaic device of claim 20, wherein said layer of a transparent conductive material comprises a layer of zinc oxide.
